(19) United States
(12) Patent Application Publication
(10) Pub. No.: US 2003/0057502 A1
(43) Pub. Date: Mar. 27, 2003

(54) Semiconductor device

(76) Inventor: Fumitoshi Yamamoto, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/214,726

(22) Filed: Aug. 9, 2002

(30) Foreign Application Priority Data
Sep. 27, 2001 (JP) 2001-297642

(51) Int. Cl. H01L 29/76

(52) U.S. Cl. 257/392

(57) ABSTRACT

The depletion N-channel transistor has a drain region formed in a circular shape and a gate region having a circular-shaped contour, disposed therein surrounding the drain region. A source region is disposed outside the gate region, surrounding the drain region and spaced a predetermined distance away from an element-isolating oxide film. For instance, a P⁺ diffused layer is formed outside the source region, and the P⁺ diffused layer spaces the source region a predetermined distance away from the element-isolating oxide film. In the P⁺ diffused layer is formed a contact hole 10 that is common to the P⁺ diffused layer and the source region, and the gate region and the drain region are disposed concentrically with each other.

### BACKGROUND OF THE INVENTION

1. Field of the Invention

The present invention relates to a semiconductor device, and more particularly relates to a semiconductor device having a depletion N-channel transistor.

2. Description of Related Art

Conventionally, a semiconductor device having a depletion N-channel transistor has been used for a microphone device for inputting voice in a cellular phone, a personal computer, and a hearing aid, for instance.

FIG. 10 is a partially broken plan view showing a conventional depletion N-channel transistor. FIG. 11 is a sectional view taken on line V-V in FIG. 10. Referring to FIG. 10 and FIG. 11, reference numeral 1 denotes a P⁻ substrate; numeral 2 denotes a P type diffused layer; numeral 3 denotes an oxide film (element-isolating oxide film); numeral 4 denotes a gate oxide film; numeral 5 denotes a gate; numeral 6 denotes a side wall (oxide film); numeral 7 denotes a N⁺ diffused layer (drain region); numeral 71 denotes a N⁺ diffused layer (source region); numeral 8 denotes a P⁺ diffused layer; numeral 9 denotes an oxide film layer; and numeral 10 denotes a contact hole.

In the depletion N-channel transistor shown in the figures, the P type diffused layer 2 is formed by diffused dopants from the surface of the P⁻ substrate 1, and serves as a back gate region of the depletion N-channel transistor. The oxide film 3 is an oxide film (element-isolating oxide film) formed by a LOCOS (Local Oxidation of Silicon) method. The oxide film is referred to as a LOCOS oxide film, herein. That is, the LOCOS oxide film 3 is an oxide film to be formed by a selective oxidation method using Si₃N₄ as an oxidation-resisting mask. The LOCOS oxide film 3 is formed across the P⁻ substrate 1 and the P type diffused layer 2 as shown in FIG. 11.

The gate oxide film 4 is formed by thermally oxidizing the surface of the P type diffused layer 2 in a thickness in the order of tens of nanometers, for instance. The N⁺ diffused layer 7 is formed by diffused dopants from the surface of the P type diffused layer 2, and serves as a drain region of the depletion N-channel transistor. The N⁺ diffused layer 7 is in contact with the LOCOS oxide film 3. In a similar manner, the N⁺ diffused layer 71 is formed by diffused dopants from the surface of the P type diffused layer 2, and serves as a source region of the depletion N-channel transistor. The P⁺ diffused layer 8 is formed by diffused dopants from the surface of the P type diffused layer 2. The gate 5 and side wall 6 are formed extending over the N⁺ diffused layer 7 and N⁺ diffused layer 71. The oxide film layer 9 is formed over the LOCOS oxide film 3, gate 5, and gate oxide film 4.

The contact hole 10 reaching the N⁺ diffused layer 7 from the surface of the oxide film layer 9 is formed by dry etching, and further the contact hole which reaches the N⁺ diffused layer 71 and P⁺ diffused layer 8 is formed. In addition, the contact hole 10 is formed such that the hole reaches the gate 5 (see FIG. 10). After that, wiring (metal wiring, not shown) is formed such that the wiring covers the contact holes 10.

Referring also to FIG. 12, when electrically connecting the N⁺ diffused area (source region) 71 and P type diffused layer (back gate region) 2 to the ground (0 volt), applying a voltage of several volts on the N⁺ diffused layer (drain region) 7, and simultaneously adjusting the voltage of the gate 5 to 0 volt (that is, when the operation voltage is applied on the depletion N-channel transistor), a current flows from the source region 71 to the drain region 7 (depicted with e⁻). This current is referred to as a channel current. Thereby, an electric field is generated between the source region 71 and the drain region 7, and a strong electric field portion 12 is formed on the side of the drain region 7. In this strong electric field portion 12 (particularly in the portion designated by the numeral 121), the number of holes (h⁺) flowing into the back gate region 2 increases. As a result, the current which flows to the back gate region 2 increases (this current is referred to as a back gate current hereinafter.).

Since the conventional semiconductor device is arranged as mentioned above, that is, since the back gate region is composed of the P-substrate 1 and P type diffused layer 2, the back gate current spreads over the semiconductor device. When the back gate current increases as mentioned above, the back gate current flowing to the whole of the semiconductor device becomes non-negligible. As a result, there has been a drawback of the inevitable generation of noise.

Incidentally, the above-mentioned microphone device for inputting and outputting voice is a combination in one, of a microphone portion (portion performing the function of the microphone) and a control portion (portion controlling the microphone portion). The control portion is composed of a diffused resistor, a depletion N-channel transistor, and an operational amplifier circuit. That is, at least the control portion consists of a semiconductor device having a depletion N-channel transistor. Therefore, when the noise due to the above defect in the depletion N-channel transistor is generated with the control portion being used for the microphone device for inputting voice, the noise is superimposed on the voice signal. When the back gate current increases, the influence caused by the noise increases. Thus, there has been a drawback that the noise gives a serious effect on the input voice.

### SUMMARY OF THE INVENTION

The present invention has been accomplished to solve the above-mentioned drawbacks. An object of the present invention is to provide a semiconductor device having a depletion N-channel transistor in which the generation of a noise can be reduced.

According to an aspect of the present invention, there is provided a semiconductor device having a depletion N-channel transistor which includes: a drain region formed in a circular shape; a gate region disposed surrounding the drain region; and a source region disposed outside the gate region, surrounding the drain region, wherein the source region is spaced a predetermined distance away from an element-isolating oxide film.

Thus, the depletion N-channel transistor is arranged such that a drain region is formed in a circular shape, a gate region is disposed surrounding the drain region, further a source region is disposed outside the gate region, surrounding the drain region, a P⁺ diffused layer is formed outside the source region, and an element-isolating oxide film is disposed spaced a predetermined distance away from the source region, the electric field within the drain region is uniformed, thereby reducing the back gate current. As a result, the noise can be reduced.

### BRIEF DESCRIPTION OF THE DRAWINGS

FIG. 1 is a partially broken plan view showing one example of the semiconductor device according to an embodiment 1 of the present invention;

FIG. 2 is a sectional view taken on line I-I in FIG. 1;

FIGS. 3A and 3B are views showing another example of the semiconductor device according to the embodiment 1 of the present invention;

FIG. 4 is an explanatory view for describing how an electric field is generated depending on the shapes of the gate region and drain region and the configuration thereof;

FIG. 5 is an explanatory view for describing how an electric field is generated when the gate region and drain region are individually formed in a circular shape;

FIGS. 6A and 6B are views showing the semiconductor device according to an embodiment 2 of the present invention;

FIGS. 7A and 7B are views showing the semiconductor device according to an embodiment 3 of the present invention;

FIGS. 8A-8F are views for describing how the current ratio is changed in the semiconductor devices;

FIG. 9 is a partially broken plan view showing the semiconductor device according to an embodiment 4 of the present invention;

FIG. 10 is a partially broken plan view showing a conventional semiconductor device;

FIG. 11 is a sectional view taken on line V-V in FIG. 10; and

FIG. 12 is a partially broken perspective view showing the conventional semiconductor device.

### DETAILED DESCRIPTION OF THE PREFERRED EMBODIMENTS

An embodiment of the present invention will be described below.

Embodiment 1

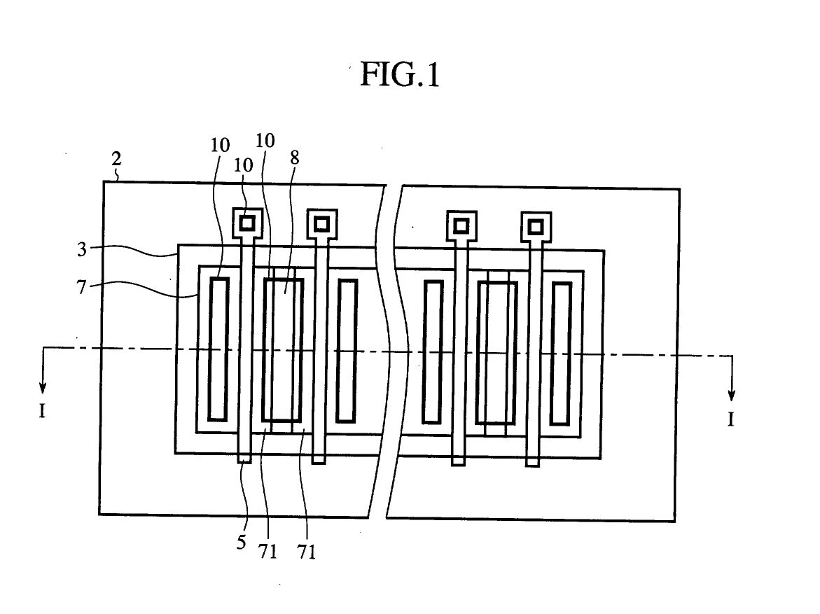

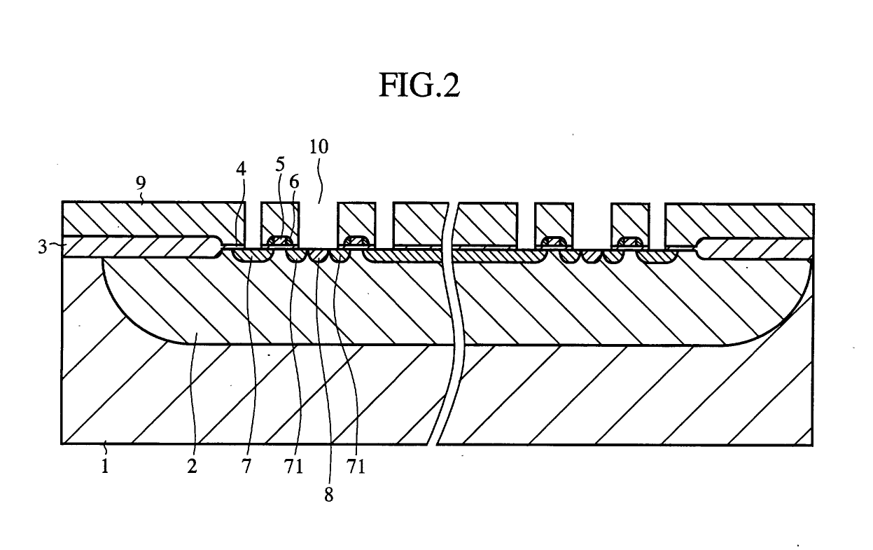

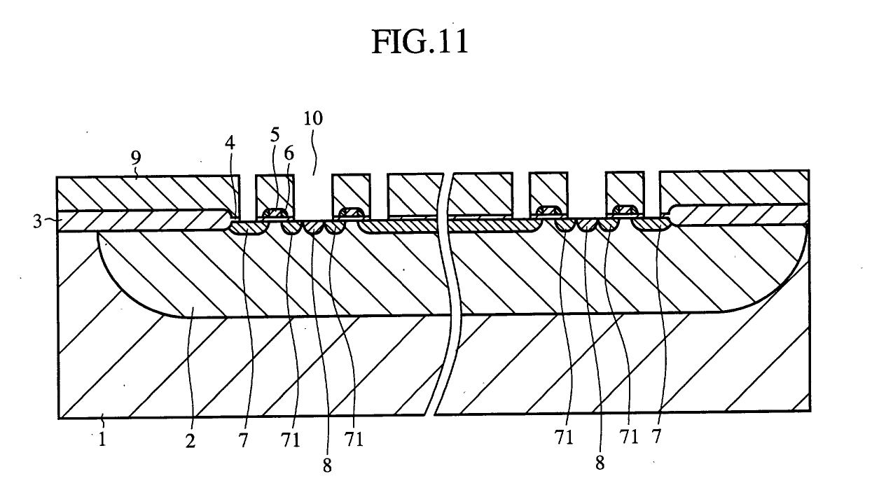

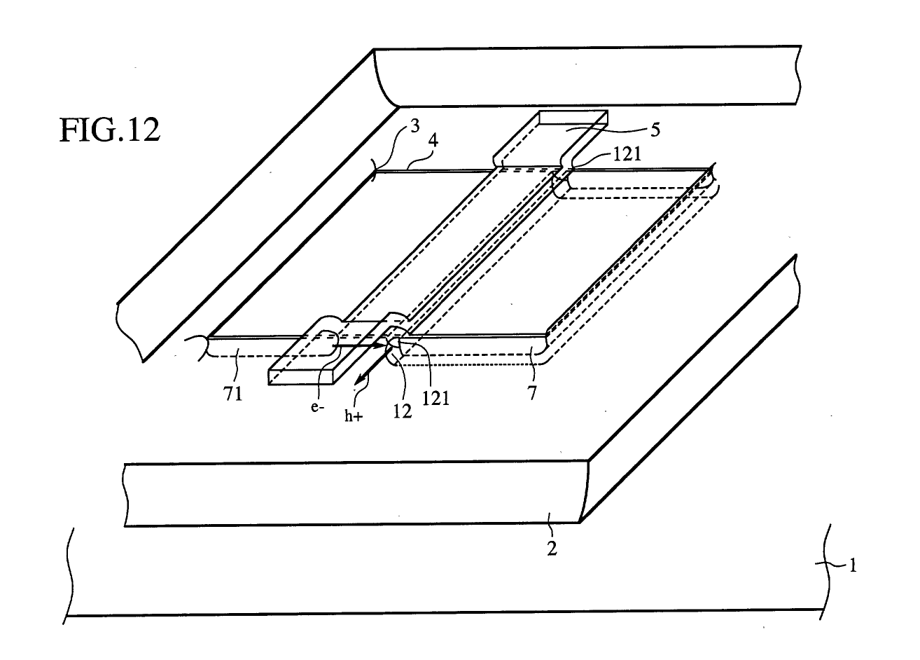

In FIG. 1 and FIG. 2, the same components as those of the depletion N-channel transistors shown in FIG. 10 and FIG. 11 are designated by similar numerals. That is, referring to FIGS. 1 and 2, reference numeral 1 denotes a P⁻ substrate; numeral 2 denotes a P type diffused layer; numeral 3 denotes a LOCOS oxide film (element-isolating oxide film); numeral 4 denotes a gate oxide film; numeral 5 denotes a gate; numeral 6 denotes a side wall (oxide film); numeral 7 denotes a N⁺ diffused layer (drain region); numeral 71 denotes a N⁺ diffused layer (source region); numeral 8 denotes a P⁺ diffused layer; numeral 9 denotes an oxide film layer; and numeral 10 denote a contact hole.

In the depletion N-channel transistor shown in the figures, the P type diffused layer 2 is formed by diffused dopants from the surface of the P⁻ substrate 1, and serves as a back gate region of the depletion N-channel transistor. The oxide film 3 is an oxide film (LOCOS oxide film, an element-isolating oxide film) formed by a LOCOS method. The oxide film 3 is formed across the P⁻ substrate 1 and P type diffused layer 2 as shown in FIG. 2.

The gate oxide film 4 is formed by thermally oxidizing the surface of the P type diffused layer 2 in a thickness in the order of tens of nanometers, for instance. The N⁺ diffused layer 7 is formed by diffused dopants from the surface of the P type diffused layer 2, and serves as a drain region of the depletion N-channel transistor. At that time, the N⁺ diffused layer 7 is formed on the P type diffused layer 2, spaced by a distance of several micrometers or more away from the LOCOS oxide film 3 by a diffusion method. In a similar manner, the N⁺ diffused layer 71 is formed by diffused dopants from the surface of the P type diffused layer 2, and serves as a source region of the depletion N-channel transistor. The P⁺ diffused layer 8 is formed by diffused dopants from the surface of the P type diffused layer 2. The gate 5 and side wall 6 are formed extending over the N⁺ ,diffused layer 7 and N⁺ diffused layer 71. The oxide film layer 9 is formed over the LOCOS oxide film 3, gate 5, and gate oxide film 4. The contact hole 10 which reaches the N⁺ diffused layer 7 from the surface of the oxide film layer 9 is formed by a dry etching method, and further the contact hole reaching the N⁺ diffused layer 71 and P⁺ diffused layer 8 is formed. In addition, the contact hole 10 is formed such that the hole reaches the gate 5 (see FIG. 1). After that, wiring (metal wiring, not shown) is formed such that the wiring covers the contact holes 10. The gate 5 and side wall 6 will be referred to as a gate region, hereinafter, and the reference numeral 5 will designate the gate region.

As mentioned above, in FIG. 1 and FIG. 2, on one side of the gate region 5 is formed the N⁺ diffused layer (drain region) 7 and on the other side of the gate region 5 is formed the N⁺ diffused layer (source region) 71. The P⁺ diffused layer 8 is placed between the N⁺ diffused layers 71. Additionally, the contact hole 10 reaching the N⁺ diffused layer 7 is formed, and the contact hole reaching the N⁺ diffused layer 71 and the P⁺ diffused layer 8 is formed. In addition, the contact hole 10 is formed such that the hole reaches the gate 5.

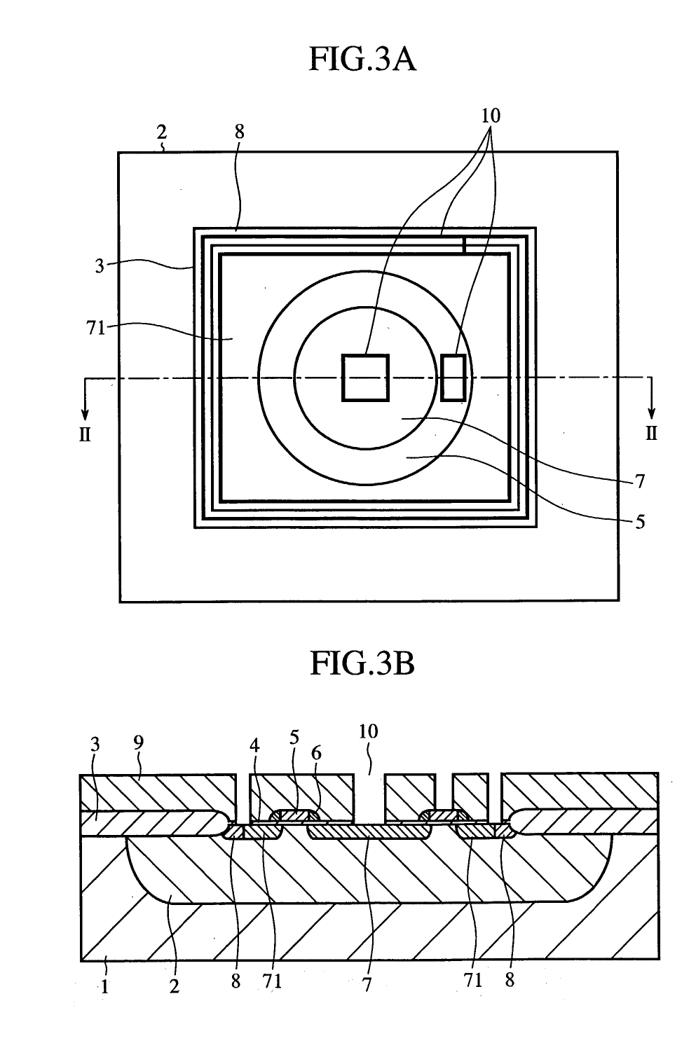

Actually, the configuration, as shown in FIGS. 3A and 3B, of the gate 5, N⁺ diffused layers 7 and 71, P⁺ diffused layer, 8, and contact hole 10 is preferable to the configuration, as shown in FIG. 1, of the gate 5, N⁺ diffused layers 7 and 71, P⁺ diffused layer 8, and, contact hole 10.

FIG. 3A is a partially broken plan view showing the depletion N-channel transistor according to the embodiment 1. FIG. 3B is a sectional view taken along line II-II in FIG. 3A. In FIGS. 3A and 3B, the same components as those of FIG. 1 and FIG. 2 are designated by similar reference numerals. The contour of a gate region 5 is formed in a circular shape. A N⁺ diffused layer (drain region) 7 is disposed within the gate region 5. In other words, the ring-shaped gate region 5 (having a circular-shaped contour) is disposed surrounding the circular-shaped drain region 7. A rectangular N⁺ diffused layer (source region) 71 is disposed outside the gate region 5. A source region 71 is spaced by a predetermined distance away from a LOCOS oxide film 3. For instance, as shown in FIG. 3B, a P⁺ diffused layer 8 is formed outside the source region 71, to thereby space the source region 71 by a predetermined distance (several micrometers or more) away from the LOCOS oxide film 3. A contact hole 10 reaching the N⁺ diffused layer 7 is formed as previously stated, and simultaneously a contact hole 10 reaching the gate region 5 is formed. In addition, a contact hole 10 reaching the N⁺ diffused layer 71 and the P⁺ diffused layer 8 is formed. In other words, the contact hole 10 that is formed in common to the P⁺ diffused layer 8 and the source, region 71. The gate region 5 and drain region 7 are disposed concentrically with each other, for instance.

Since in the depletion N-channel transistor shown in FIG. 1 and FIG. 2, the N⁺ diffused layer 7 is spaced apart by several micrometers or more from the LOCOS oxide film 3, an electric field generated in a region in which the drain region 7 superimposes the gate 5 would be reduced. As a result, the back gate current can be reduced. Thereby, the noise caused by the back gate current can be lowered.

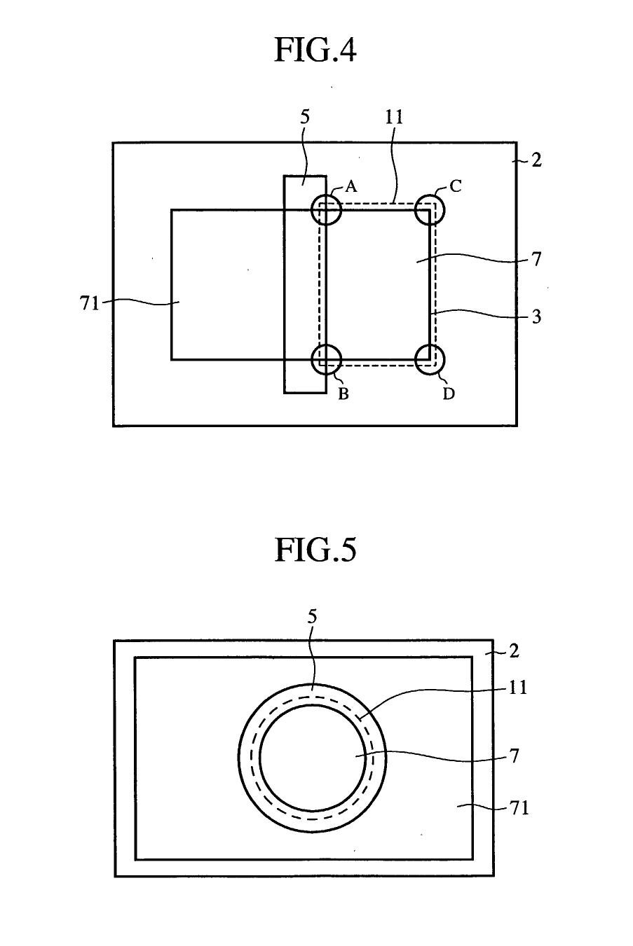

To be more specific, as shown in FIG. 4, because in the drain region 7 the corner portions (designated by the characters A-D in FIG. 4) are right-angled, the corner portions A-D have stronger electric fields than other portions (the straight portions, for instance) have. since the gate region 5 exists on the surface of the drain region 7 in the corner portions A and B in which the drain region 7 contacts the gate region 5, a depletion layer 11 does not expand over the surface of the drain region 7 when the gate voltage is close to the threshold voltage (VTH), for instance. Therefore, the electric field generated in portions in which the drain region 7 crosses the gate region 5 (corner portions A and B) particularly strengthens.

On the other hand, in FIG. 1 and FIG. 2, the drain region 7 is spaced by a distance of several micrometers or more away from the LOCOS oxide film 3, as previously stated. That is, since the edge portion of the LOCOS oxide film 3 does not exist in the vicinity of the drain region 7, the electric field generated in a portion in which the drain region 7 crosses the gate region 5 would be reduced. As a result, the noise can be reduced.

In addition, when as described in FIG. 3A and FIG. 3B, the drain region 7 is arranged to have a circular shapes, and simultaneously the configuration of the gate region 5, drain region 7, source region 71, P⁺ diffused layer 8 and contact hole 10 is determined, the depletion layer 11 is formed along the contour of the drain region 7 as shown in FIG. 5. Since there exists no corner portions within the drain region 7, no electric field is locally concentrated; resulting in uniforming the electric field in the drain region 7. Therefore, the back gate current generated by the accumulated or concentrated electric field can be reduced. As is apparent from the fact, the contour of the gate 5 is not limited to the circular shape (circular arc), and can be quadrangular, for instance.

As mentioned above, according to the embodiment 1, since the semiconductor device having a depletion N-channel transistor is arranged such that the drain region is formed in a circular shape, and the drain region is located within the gate region, the electric field generated within the drain region is made uniform. As a result, the back gate current can be reduced.

In addition, according to the embodiment 1, the semiconductor device is arranged such that the source region is disposed surrounding the drain region, outside the gate region, and the contact hole that is formed in common to the source region and the P⁺ diffused layer as the source region is spaced by several micrometers or more away from the LOCOS oxide film (for instance, the P⁺ diffused layer 8 is formed outside the source region 71). Thus, a rate at which the back gate current spreads can be reduced.

Embodiment 2

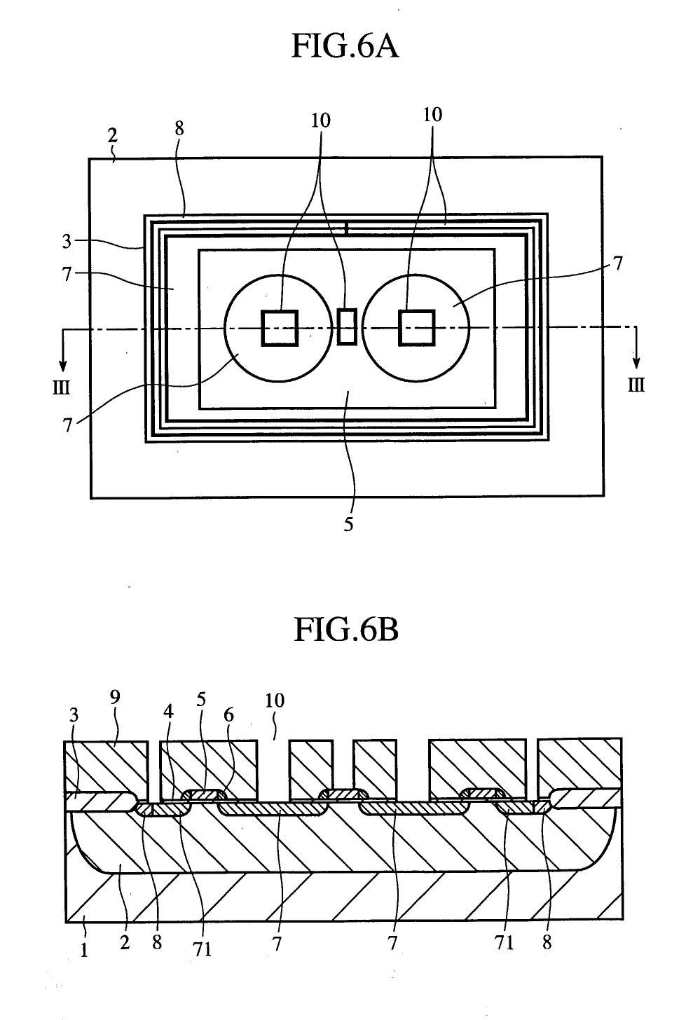

FIG. 6A is a partially broken plan view showing the depletion N-channel transistor according to an embodiment 2. FIG. 6B is a sectional view taken on line III-III in FIG. 6A. In FIG. 6A and FIG. 6B, the same components as those of the depletion N-channel transistors shown in FIG. 3A and FIG. 3B are designated by similar numerals. In the example shown in the figures, the contour of the gate region 5 is formed in a rectangular shape. A pair of circular-shaped drain regions 7 (referred to as the first drain region portion and second drain region portion, hereinafter) are disposed spaced by a predetermined distance away from each other inside the gate region 5. The source region 71 is formed outside the gate region 5, and the P⁺ diffused layer 8 is disposed outside the source region 71. Additionally, the P⁺ diffused layer 8 separates the source region 71 by several micrometers or more from the LOCOS oxide film 3. The contact holes 10 reaching the first and second drain region portions 7 are formed, respectively, as mentioned above, and simultaneously the contact hole 10 reaching the gate region 5 is formed between the first and second drain region portions 7. In addition, the contact hole 10 reaching the source region 71 and the P⁺ diffused layer 8 is formed.

In FIG. 6A and FIG. 6B, the contact hole 10 reaching the gate region 5 is formed between the first and second drain region portions 7. That is, because no contact hole is formed on the channel, the characteristic of the depletion N-channel transistor is not deteriorated even if damage is nearly caused to the depletion N-channel transistor when forming the contact hole.

Moreover, since the semiconductor device is arranged such that the first and second drain region portions are individually formed in a circular shape, and the first and second drain region portions are located inside the gate region, the electric field generated within the drain region is made uniform. As a result, the back gate current can be reduced. In addition, the contour of the gate region 5 is not limited to a rectangular shape, but the gate region 5 may be formed in another shape. The back gate current can be reduced also in this case, as long as the first drain region portion has a circular shape and the second drain region portion has a circular shape.

In the example shown in FIG. 6A and FIG. 6B, the first and second drain region portions 7 are disposed inside the gate region 5. The depletion N-channel transistor can be arranged such that a first to a m-th drain region portions (“m” is an integer that is 3 or more, and 3-th represents “third”.) are similarly disposed spaced a predetermined distance away from each other inside the gate region 5.

As mentioned above, according to the embodiment 2, the characteristic of the depletion N-channel transistor is not deteriorated and further the noise can be reduced because of the reduction of the back gate current.

Embodiment 3

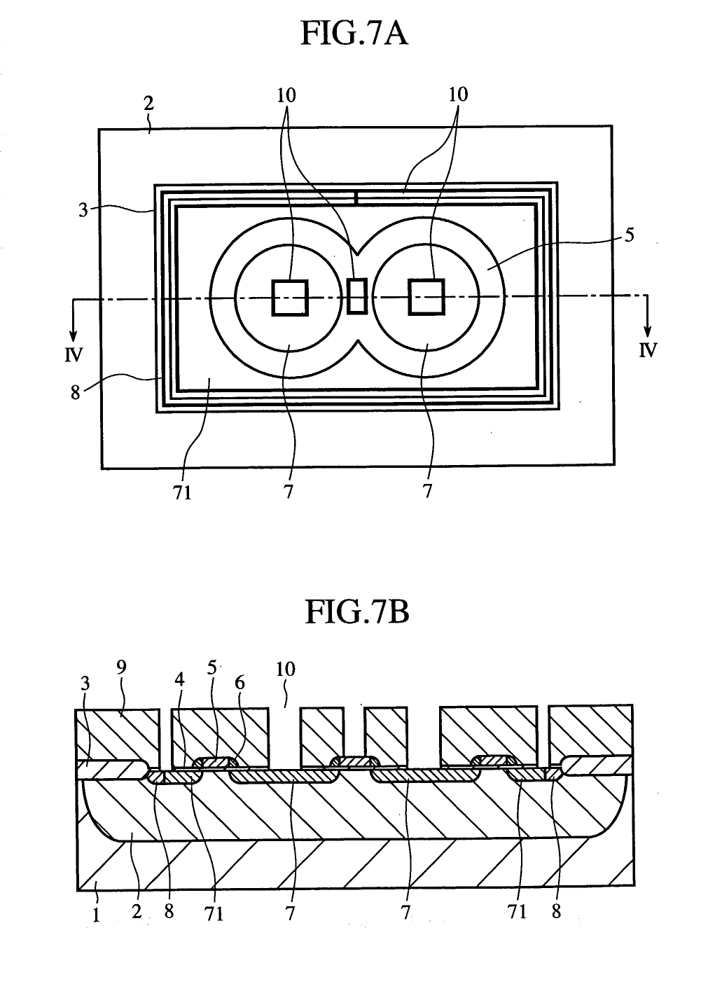

FIG. 7A is a partially broken plan view showing the depletion N-channel transistor according to an embodiment 3. FIG. 7B is a sectional view taken along line IV-IV in FIG. 7A. In FIG. 7A and FIG. 7B, the same reference numerals designate the same components as those of the depletion N-channel transistor shown in FIG. 3. In the example shown in the figure, the contour of the gate region 5 is formed in a circular-arc shape and it looks as if it is 8-shaped. That is, the contour of the gate region 5 is formed in a 8-shape in which the first circular-arc and the second circular-arc are jointed. The first and second drain region portions 7 are disposed spaced by a predetermined distance away from each other inside the gate region 5. The first drain region portion 7 is disposed concentric with the first circular arc located left in the figure, for instance, and the second drain region portion 7 is disposed concentric with the second circular arc located right in the figure.

The source region 71 is formed outside the gate region 5, and the P⁺ diffused layer 8 is disposed outside the source region 71. The P⁺ diffused layer 8 separates the source region 71 several micrometers or more from the LOCOS oxide film 3. The contact holes 10 reaching the first and second drain region portions 7 are individually formed, as mentioned above, and simultaneously the contact hole 10 reaching the gate region 5 is formed between the first and second drain region portions 7. In addition, the contact hole 10 reaching the source region 71 and the P⁺ diffused layer 8 is formed.

In FIG. 7A and FIG. 7B, the contact hole 10 reaching the gate region 5 is formed between the first and second drain region portions. That is, because the contact hole 10 is not formed on the channel, the characteristic of the depletion N-channel transistor is not deteriorated even if damage is nearly caused to the depletion N-channel transistor when forming the contact hole.

Moreover, since the semiconductor device is arranged such that the first and second drain region portions are formed individually in a circular shape, and the first and second drain region portions are located inside the gate region, the electric field generated within the drain region is made uniform. As a result, the back gate current can be reduced.

In addition, since the contour of the gate region 5 is formed in an 8-shape concentric with the first and second drain region portions 7, the width of the gate can be precisely determined.

In the example shown in FIG. 7A and FIG. 7B, the first and second drain region portions 7 are disposed inside the gate region 5. Similarly, the depletion N-channel transistor can be arranged such that a first to a m-th drain region portions (m is an integer that is 3 or more, and 3-th represents “third.”) are disposed spaced a predetermined distance away from each other inside the gate region 5.

As mentioned above, according to the embodiment 3, the characteristic of the depletion N-channel transistor is not deteriorated and further the noise can be reduced because of the reduction of the back gate current. Additionally, the width of the gate can be precisely determined.

Embodiment 4

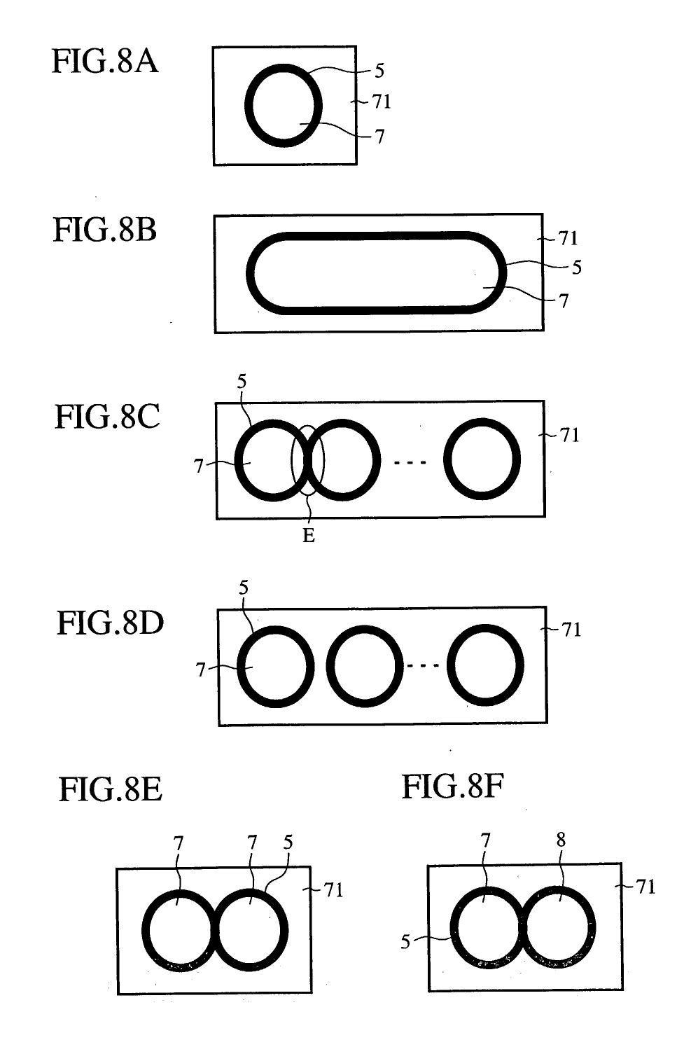

Referring to FIGS. 8A-8F, let the structure shown in FIG. 8A be one basic unit. Suppose that the structure shown in FIG. 8B is used in order to increase the amount of current passing through the basic unit (the unit amount of current) by a factor of N times (N is an integer larger than one.). FIG. 8A is the figure that is obtained by simplifying FIG. 3A. The basic unit is a basic structure corresponding to one depletion N-channel transistor. In FIG. 8B, the gate region 5 is formed in a track shape, and the area of the drain region 7 is increased N-fold compared with the area of the basic unit. That is, the case in which the structure shown in FIG. 8B is used will next be discussed as below. However, merely by increasing the area of the drain region 7 by a factor of N times, the amount of current passing through the new structure shown in FIG. 8B cannot become increased to N times the unit amount of current because the channel is formed in patterns depending on whether the formation. is done in the straight portion or in the corner portion of the gate region 5. That is, because the forming patterns of the channel depend on whether the formation is performed in the straight portion or in the corner portion of the gate region 5, even if the area of the drain region 7 is N-fold increased, the ratio of the current cannot be increased corresponding to the area ratio.

Furthermore, when N pieces of basic units are serially formed by disposing the basic units of the gate region 5 in a partially overlapping arrangement as shown in FIG. 8C, the channel cannot be formed in the part shown with the character E in the figure. That is, if N pieces of basic units of gate region 5 are serially formed such that the N pieces of basic units are partially overlapped, the current passing therethrough cannot be also increased to N times the unit amount of current. In other words, the current ratio corresponding to the number of the basic units cannot be obtained.

On the other hand, when N pieces of basic units are disposed spaced a predetermined distance away from each other as shown in FIG. 8D, the current passing therethrough can be increased to N times the unit amount. However, the total area of the drain region 7 increases beyond N times the basic unit area.

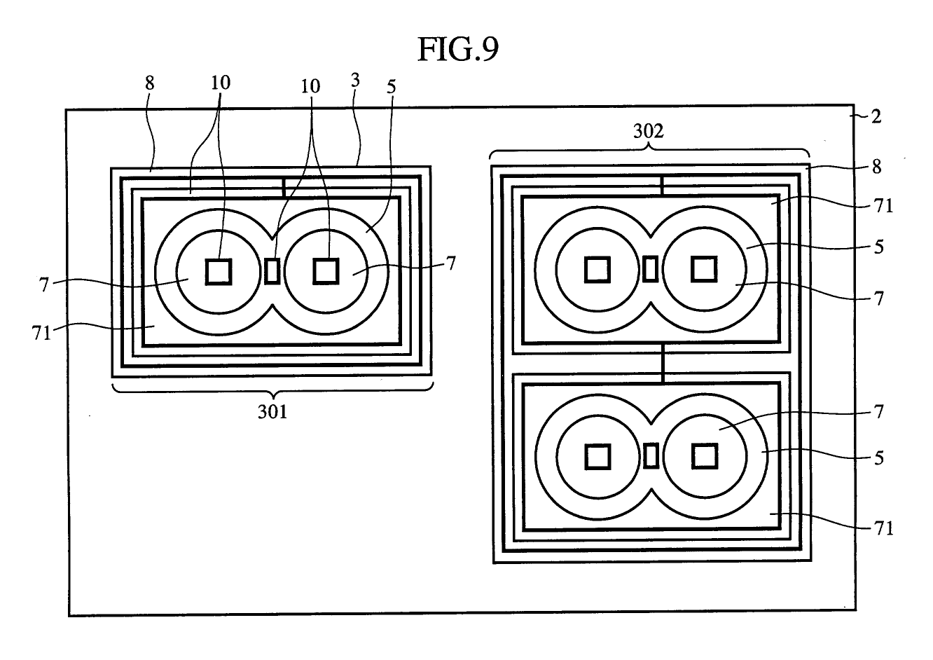

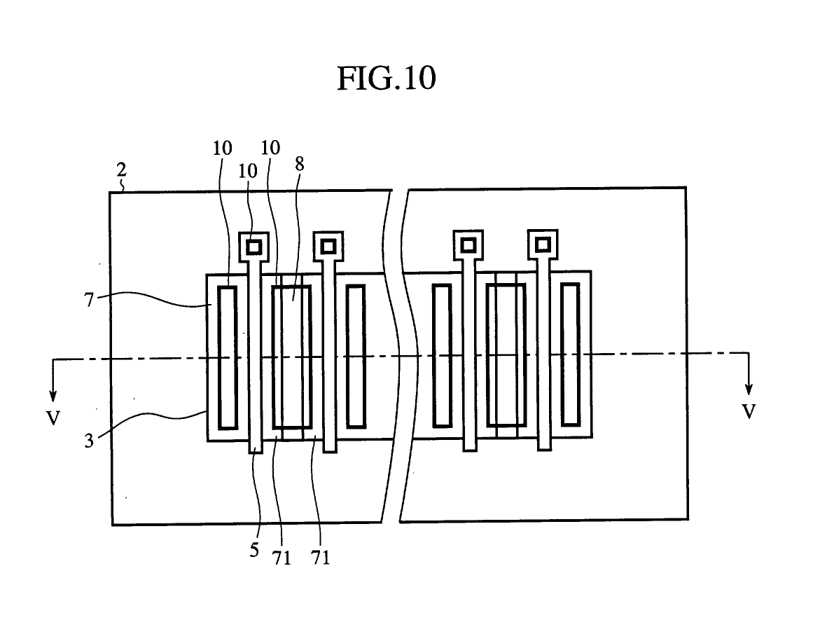

Then, let the structure shown in FIG. 8E be one new basic unit. FIG. 8E is a figure that is obtained by simplifying FIG. 7A. The new basic unit shown in FIG. 8E has the same area as that of the basic unit shown in FIG. 8A. Referring also to FIG. 9, now let the structure shown in FIGS. 7A and 7B be the basic unit 301. A P⁺ diffused layer 8 is formed in the same condition described referring to FIGS. 7A and 7B, and as described referring to FIGS. 7A and 7B, gate regions 5, drain regions 7, and source regions 71 are formed on P type diffused layer 2. That is, when the structure 302 having two basic units 301 is formed, the current passing through the structure 302 equals two times the current passing through the basic unit 301. That is, when N pieces of basic units are formed, the current passing therethrough equals N times the current passing through the basic unit. In addition, in the basic unit 301, when one of the first and second drain region portions 7 (the right drain region portion 7 in FIG. 8F) is changed to a P⁺ diffused layer 8 as shown in FIG. 8F, the current passing through the changed structure becomes half compared with the current passing through the basic unit 301.

Thus, when N pieces of basic units are formed with the structure shown in FIGS. 7A and 7B as the basic unit 301, the current passing through the formed units becomes N times the current passing through the basic unit. When one of the first and second drain regions 7 in the basic unit 301 is changed to a P⁺ diffused layer 8, the current passing through the changed structure becomes half the current passing through the basic unit 301. Thereby, it is possible to reduce the area of the semiconductor device compared with obtaining the current ratio by use of the structure shown in FIG. 3.

As mentioned above, according to the embodiment 4, it is possible to reduce the area of the semiconductor device and precisely obtain the current ratio. In addition, the back gate current can be reduced without deteriorating the characteristic of the depletion N-channel transistor, to thereby reduce the noise. Additionally, it is possible to precisely determine the gate width.

What is claimed is:

1. A semiconductor device having a depletion N-channel transistor, said transistor including:
a drain region formed in a circular shape;
a gate region disposed surrounding the drain region; and
a source region disposed outside the gate region, surrounding the drain region,
wherein the source region is spaced by a predetermined distance away from an element-isolating oxide film.

2. The semiconductor device according to claim 1, wherein a P⁺ diffused layer is formed outside the source region and the source region is spaced due to the P⁺ diffused layer by a predetermined distance away from the element-isolating oxide film.

3. The semiconductor device according to claim 2, wherein a contact hole also reaching the source region in common is formed on the P⁺ diffused layer.

4. The semiconductor device according to claim 1, wherein the gate region has a circular-shaped contour.

5. The semiconductor device according to claim 4, wherein the gate region and the drain region are disposed concentrically with each other.

6. The semiconductor device according to claim 1, wherein the drain region has a first drain region portion and a second drain region portion that are spaced by a predetermined distance away from each other and individually formed in a circular shape.

7. The semiconductor device according to claim 6, wherein a contact hole reaching the gate region is formed between the first drain region portion and the second drain region portion.

8. The semiconductor device according to claim 6, wherein the gate region has a rectangular-shaped contour.

9. The semiconductor device according to claim 6, wherein the gate region has an 8-shaped contour formed by joining a first circular arc portion and a second circular arc portion, the first drain region portion is disposed inside the first circular arc portion, and the second drain region portion is disposed inside the second circular arc portion.

10. The semiconductor device according to claim 9, wherein the first circular arc portion and the second circular arc portion are disposed concentrically with the first drain region portion and the second drain region portion, respectively.

11. The semiconductor device according to claim 9, wherein a P⁺ diffused layer is formed instead of the second drain region portion.

12. The semiconductor device according to claim 1, wherein the drain region has a first to a m-th (m: integer of 3 or more) circular-shaped drain region portions spaced by a predetermined distance away from each other.
